(19) United States
(12) Patent Application Publication
(10) Pub. No.: US 2006/0267124 A1
(43) Pub. Date: Nov. 30, 2006

(54) Light receiving device

(75) Inventor: Tomohiro Yamazaki, Kyoto-shi (JP)

Correspondence Address: HOGAN & HARTSON L.L.P., 1999 AVENUE OF THE STARS, SUITE 1400, LOS ANGELES, CA, 90067, US

(73) Assignee: ROHM CO., LTD.

(21) Appl. No.: 11/430,374

(22) Filed: May 8, 2006

(30) Foreign Application Priority Data
May 27, 2005 (JP) JP2005-155128

(51) Int. Cl. H01L 31/0232

(52) U.S. Cl. 257/432; 257/436; 257/E33.068

(57) ABSTRACT

Light incident to a photodiode can be reflected to a depletion layer by providing a reflection plane in a recess. The reflection plane reflects the light incident to the photodiode toward the depletion layer, and a substrate and/or a semiconductor layer transmits the light to the depletion layer. The inside of a housing is filled with a diffuser which diffuses the light so as to cover the photodiode. Therefore, part of the light incident to the housing can be diffused and caused to reach the depletion layer by the diffuser.

The present application is based on, and claims priority from, J.P. Application 2005-155128, filed May 27, 2005, the disclosure of which is hereby incorporated by reference herein in its entirety.

### BACKGROUND OF THE INVENTION

1. Field of the Invention

The present invention relates to a light receiving device which can efficiently receive light using a reflection plane or a housing for diffusing the light.

2. Description of the Related Art

For example, Japanese Patent Application Laid-Open No. 2000-77683 discloses an invention in which a resin sealing body with which a photodiode or a substrate of the photodiode is covered includes a reflection plane and a lens in order to focus light on a light receiving surface of the photodiode. The photodiode is covered with the resin sealing body. The resin sealing body includes one convex lens in a side face and a groove which becomes a reflection plane in an upper surface. After the light incident from a side of the convex lens of the resin sealing body is caused to converge by the convex lens, the light is focused on the light receiving surface through the reflection plane. The light incident from the thin side face of the photodiode can be focused on the light receiving surface by providing the reflection plane and the convex lens in the resin sealing body.

For example, Japanese Patent Application Laid-Open No. 2001-308367 discloses an invention in which the light which is incident from the light receiving surface of the photodiode and passes through the depletion layer is reflected by the reflection plane and incident to the depletion layer again by providing the reflection plane adjacent to the side of the depletion layer opposite to the light receiving surface. The light passing through the depletion layer is reflected to the depletion layer, which allows improvement of an optical absorption coefficient of the photodiode.

Japanese Patent Application Laid-Open No. 2000-164896, for example, also discloses an invention in which diffuse reflection and attenuation of the incident light caused by a filler are reduced by decreasing a mixture amount of filler. The filler is mixed into the resin sealing body, which covers the photodiode, in order to release stress.

However, in inventions disclosed in Japanese Patent Application Laid-Open Nos. 2000-77683 and 2001-308367, there is a problem that the light cannot be focused on the depletion layer. That is, in the invention disclosed in Japanese Patent Application Laid-Open No. 2000-77683, the whole of the light reflected by the reflection plane is not incident to the depletion layer due to a depth and an angle of the reflection plane, a distance between the light receiving surface and the reflection plane, a shape of the convex lens, and the like. In the invention disclosed in Japanese Patent Application Laid-Open No. 2001-308367, because the reflection plane is located across the depletion layer from the light receiving surface, only the light passing through the depletion layer is reflected toward the depletion layer. The present invention is achieved to solve the above-mentioned problem, it is an object of the invention is to provide a light receiving device in which part of the light incident to the photodiode can be focused on the depletion layer of the photodiode and thereby the light can efficiently be received.

In the invention disclosed in Japanese Patent Application Laid-Open No. 2000-164896, because the filler having no light-reflecting property is mixed in the resin sealing body, the light incident to the photodiode does not always reach the depletion layer. The present invention is achieved to solve the above-mentioned problem, it is another object of the invention is to provide a light receiving device in which part of the light incident to the photodiode is caused to reach the depletion layer and thereby the light can efficiently be received.

### SUMMARY OF THE INVENTION

In order to achieve the object, a first aspect of the invention provides a light receiving device including a photodiode which has a depletion layer on a side of one surface in two surfaces opposite to each other; and a recess which is provided in a substrate and/or a semiconductor layer on the side of the other surface opposite to one surface of the photodiode, wherein the recess has a reflection plane which reflects light incident from the side of the other surface of the photodiode toward the depletion layer, and the light transmits the inside of the substrate and/or the semiconductor layer to the depletion layer.

The recess has the reflection plane which reflects the light incident from the side of the other surface of the photodiode toward the depletion layer, and the light transmits the inside of the substrate and/or the semiconductor layer to the depletion layer. Therefore, the light incident from the side of the other surface of the photodiode can be reflected to the depletion layer. Accordingly, in the first aspect of the invention, part of the light incident to the photodiode can be focused onto the depletion layer of the photodiode, which enables the provision of the light receiving device which can efficiently receive the light.

A second aspect of the invention provides light receiving device including a photodiode which has a depletion layer on a side of one surface in two surfaces opposite to each other; a recess forming layer in which a recess is formed, the recess forming layer being deposited on the side of one surface of the photodiode or on the side of the other surface opposite to one surface; and the recess which is formed in the recess forming layer, wherein the recess has a reflection plane which reflects light incident from the side of the recess forming layer toward the depletion layer.

The recess has the reflection plane which reflects the light incident from the side of the recess forming layer of the photodiode toward the depletion layer, which allows the light incident from the side of the recess forming layer of the photodiode to be reflected to the depletion layer. Accordingly, in the second aspect of the invention, part of the light incident to the photodiode can be focused onto the depletion layer of the photodiode, which enables the provision of the light receiving device which can efficiently receive the light.

In the first or second aspect of the invention, a shape of the recess may be a part of a paraboloid.

When the shape of the recess is formed as a part of the paraboloid, the light incident from the side of the recess forming layer of the photodiode can efficiently be reflected to the depletion layer. Accordingly, in the second aspect of the invention, part of the light incident to the photodiode can be focused onto the depletion layer of the photodiode by forming the shape of the recess as a part of the paraboloid, which enables the provision of the light receiving device which can efficiently receive the light.

A third aspect of the invention provides a light receiving device including a photodiode which has a depletion layer on a side of one surface in two surfaces opposite to each other; a plate-shape body which is arranged on the side of one surface of the photodiode or on the side of the other surface opposite to one surface; and a hole portion which penetrates the plate-shape body, wherein the hole portion has a reflection plane which reflects light incident from the side of the plate-shape body toward the depletion layer.

The hole portion has the reflection plane which reflects the light incident from the side of the plate-shape body of the photodiode toward the depletion layer, which allows the light incident from the side of the plate-shape body of the photodiode to be reflected to the depletion layer. Accordingly, in the third aspect of the invention, part of the light incident to the photodiode can be focused onto the depletion layer of the photodiode, which enables the provision of the light receiving device which can efficiently receive the light.

In the third aspect of the invention, the shape of the hole portion may be a part of the paraboloid.

When the shape of the hole portion is formed as a part of the paraboloid, the light incident from the side of the plate-shape body of the photodiode can efficiently be reflected to the depletion layer. Accordingly, in the third aspect of the invention, part of the light incident to the photodiode can be focused onto the depletion layer of the photodiode by forming the shape of the hole portion as a part of the paraboloid, which enables the provision of the light receiving device which can efficiently receive the light.

In the second or third aspect of the invention, the depletion layer may be arranged in a focus of the paraboloid.

The light incident to the reflection plane is focused on the depletion layer, which is of the focus, by arranging the depletion layer in the focus of the paraboloid. Accordingly, in the second or the third aspect of the invention, part of the light incident to the photodiode can be focused onto the depletion layer of the photodiode by arranging the depletion layer in the focus of the paraboloid, which enables the provision of the light receiving device which can efficiently receive the light.

A fourth aspect of the invention provides a light receiving device including a photodiode which has a depletion layer on a side of one surface in two surfaces opposite to each other; a housing which accommodates the photodiode, at least one surface of the housing being opened; and a diffuser with which an inside of the housing is filled so as to cover the photodiode, the diffuser diffusing light.

When the inside of the housing is filled with the diffuser for diffusing the light so as to cover the photodiode, part of the light incident to the housing can be diffused by the diffuser and caused to reach the depletion layer. Accordingly, in the fourth aspect of the invention, part of the light incident to the photodiode can be caused to reach the depletion layer of the photodiode, which enables the provision of the light receiving device which can efficiently receive the light.

A fifth aspect of the invention provides a light receiving device including a photodiode which has a depletion layer on a side of one surface in two surfaces opposite to each other; a housing which accommodates the photodiode, at least one surface of the housing being opened; and a diffuser which is provided in the housing, the diffuser diffusing light incident to the depletion layer of the photodiode.

When the diffuser which diffuses the light incident to the photodiode is provided in the housing, part of the light incident to the housing can be diffused by the diffuser and caused to reach the depletion layer. Accordingly, in the fifth aspect of the invention, part of the light incident to the photodiode can be caused to reach the depletion layer of the photodiode, which enables the provision of the light receiving device which can efficiently receive the light.

In the fourth or fifth aspect of the invention, the diffuser may be made of plural mixed transparent materials having different refractive indexes.

When the diffuser is made of the plural mixed transparent materials having different refractive indexes, part of the light incident to the housing is not absorbed, but part of the light can be refracted to reach the depletion layer. Accordingly, in the fourth or fifth aspect of the invention, the diffuser is made of the plural mixed transparent materials having different refractive indexes, which allows part of the light incident to the photodiode to be caused to reach the depletion layer of the photodiode. This enables the provision of the light receiving device which can efficiently receive the light.

In the fourth or fifth aspect of the invention, the diffuser may be arranged while removed a portion immediately above the depletion layer.

When the diffuser is arranged while removed the portion immediately above the depletion layer, part of the light incident to the housing can reach the depletion layer without diffusion or refraction. Accordingly, in the fourth or fifth aspect of the invention, the diffuser is arranged while removed the portion immediately above the depletion layer, which allows part of the light incident to the photodiode to be caused to reach the depletion layer of the photodiode. This enables the provision of the light receiving device which can efficiently receive the light.

According to the invention, the light receiving device which can efficiently receive the light can be provided.

### BRIEF DESCRIPTION OF THE DRAWINGS

FIG. 1 is a sectional view showing a light receiving device 101 of one embodiment according to a first aspect of the invention;

FIG. 2 is a top view showing the light receiving device 101 of another embodiment according to the first aspect of the invention;

FIG. 3 is a top view showing the light receiving device 101 of another embodiment according to the first aspect of the invention;

FIG. 4 is a sectional view showing a light receiving device 102 of one embodiment according to a second aspect of the invention;

FIG. 5 is a sectional view showing a light receiving device 103 of one embodiment according to a third aspect of the invention;

FIG. 6 is a sectional view showing the light receiving device 103 of another embodiment according to the third aspect of the invention;

FIG. 7 is a sectional view showing the light receiving device 103 of another embodiment according to the third aspect of the invention;

FIG. 8 is a sectional view showing the light receiving device 103 of another embodiment according to the third aspect of the invention;

FIG. 9 is a sectional view showing a light receiving device 104 of one embodiment according to a fourth aspect of the invention;

FIG. 10 is a sectional view showing the light receiving device 104 of another embodiment according to the fourth aspect of the invention;

FIG. 11 is a sectional view showing a light receiving device 105 of one embodiment according to a fifth aspect of the invention;

FIG. 12 is a sectional view showing the light receiving device 101 of another embodiment according to the first aspect of the invention;

FIG. 13 is a sectional view showing another light receiving device of the first embodiment;

FIG. 14 is a sectional view showing a photodiode 10 according to the first aspect of the invention;

FIG. 15 shows a relationship between a reflection-plane setting angle and a reflection-plane height according to the first aspect of the invention;

FIG. 16 is a sectional view showing the light receiving device 103 of another embodiment according to the third aspect of the invention;

FIG. 17 is a sectional view showing the light receiving device 102 of another embodiment according to the second aspect of the invention; and

FIG. 18 is a sectional view showing the light receiving device 102 of another embodiment according to the second aspect of the invention.

101, 102, 103, 104, 105 indicate a light receiving device, 10 indicates a photodiode, 11 indicates a depletion layer, 12 indicates AR coating, 13 indicates an air layer, 20 indicates a recess forming layer, 21 indicates a recess, 22 indicate a reflection plane, 23 indicates a electrode, 24 indicates a plated-interconnection, 30 indicates a plate-shape body, 31 indicates a through hole, 32 indicates an interconnection, 33 indicates a bump, 40 indicates a substrate, 50 indicates a housing, 51 indicates a diffuser, 52 indicates a diffuser plate, 61 indicates a center line, 71 indicates an optical path, 81 indicates a trans-impedance amplifier, 82 indicates an external IC, 90 indicates an incident light, 91 indicates an incident-light incident angle, 92 indicates a reflection-plane setting angle, 93 indicates a recess opening maximum diameter, 94 indicates a reflection-plane height, 95 indicates a recess opening minimum diameter and 96 indicates a distance.

### DESCRIPTION OF THE PREFERRED EMBODIMENT

Preferred embodiments of the invention will be described in detail below with reference to the drawings. However, the invention is not limited to the following embodiments.

### First Embodiment

A first embodiment is a light receiving device including a photodiode which has a depletion layer on a side of one surface in two surfaces opposite to each other; and a recess which is provided in a substrate and/or a semiconductor layer on the side of the other surface opposite to one surface of the photodiode, wherein the recess has a reflection plane which reflects light incident from the side of the other surface of the photodiode toward the depletion layer, and the light transmits the inside of the substrate and/or the semiconductor layer to the depletion layer.

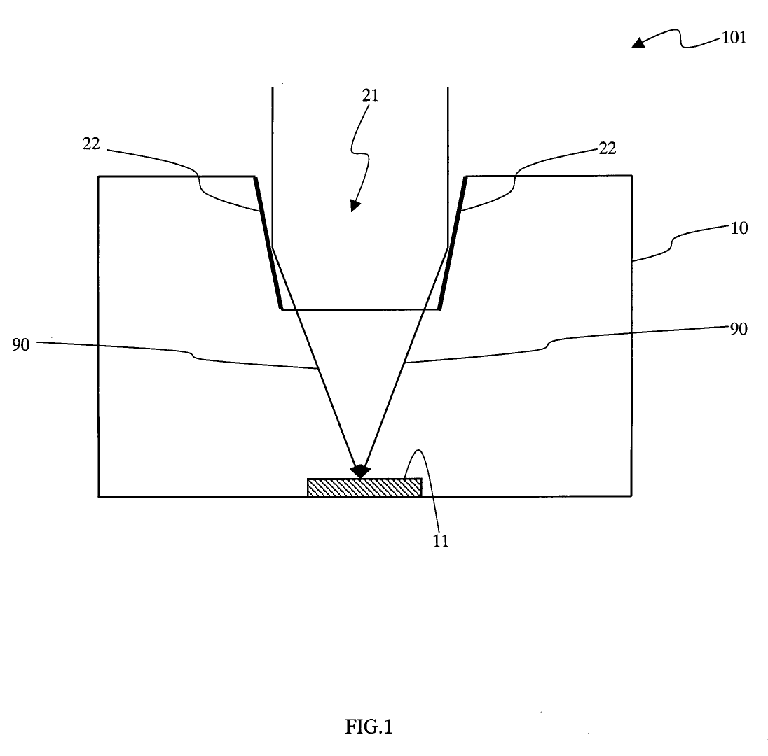

FIG. 1 is a sectional view showing a light receiving device 101 according to a first embodiment. Referring to FIG. 1, the light receiving device 101 includes a photodiode 10, a depletion layer 11, a recess 21, and a reflection plane 22. It is assumed that the light incident to the reflection plane 22 is an incident light 90.

The photodiode 10 which is comprised of a substrate and a semiconductor layer converts the light absorbed by the depletion layer 11 into an electric signal. Examples of the substrate of the photodiode 10 include a sapphire substrate and a semiconductor substrate made of group-IV single-element semiconductor such as silicon (Si) and germanium (Ge), group-III-V compound semiconductor such as indium phosphide (InP), galliumarsenide (GaAs), indium galliumarsenide (InGaAs), gallium indium nitrogen arsenide (GaInNAs), aluminum gallium indium nitride (AlGaInN), aluminum indium gallium phosphide (AlInGaP), indium gallium arsenic phosphide (InGaAsP), and indium gallium aluminum arsenide (InGaAlAs), or group-II-VI compound semiconductor such as zinc oxide (ZnO), zinc selenide (ZnSe), and cadmium telluride (CdTe). Examples of the semiconductor layer of the photodiode 10 include a p-type semiconductor layer and an n-type semiconductor layer. The p-type semiconductor layer and the n-type semiconductor layer are deposited on the semiconductor substrate by adding an impurity to group-IV single-element semiconductor such as silicon and germanium, group-III-V compound semiconductor such as indium phosphide, gallium arsenide, indium gallium arsenide, gallium indium nitrogen arsenide, aluminum gallium indium nitride, aluminum indium gallium phosphide, indium gallium arsenic phosphide, and indium gallium aluminum arsenide, or group-II-VI compound semiconductor such as zinc oxide, zinc selenide, and cadmium telluride. Examples of a type of the photodiode 10 include a pn-photodiode, a pin-photodiode, and an avalanche photodiode.

A silicon semiconductor layer will be described by way of example. The desired impurity such as boron (B) and phosphorous (P) is diffused such that a depletion layer 11 is formed on one surface side. An ion injection method and a thermal diffusion method can be used as the impurity diffusion method. In the case where the impurity is diffused by the ion injection method, heat treatment is desirably performed to the silicon semiconductor layer. Thus, the depletion layer 11 is formed on one surface side of the silicon semiconductor layer through the above process.

In the recess 21, the surfaces except for the surface on the side of the depletion layer 11 are utilized for the reflection plane 22. In FIG. 1, the substrate does not distinguish from the semiconductor layer in the photodiode 10. However, the recess 21 is provided in the substrate and/or semiconductor layer on the side of the surface opposing the surface in which the depletion layer 11 of the photodiode 10 is formed. The recess 21 may be provided in the substrate of the photodiode 10 or in the semiconductor layer of the photodiode 10. The recess 21 may also be provided across the substrate and the semiconductor layer of the photodiode 10.

The recess 21 can be formed by etching. For example, when reactive ion etching is performed to the silicon semiconductor layer using an appropriate reactant gas such as CBrF4, the etching toward a transversal direction of the photodiode 10 does not progress by action of a sidewall protection film generated in the silicon semiconductor layer. When an etching time is adjusted and a circular photomask is used, the shape of the recess 21 can be formed as a part of a conical surface. When the etching time is adjusted and a square photomask is used, the shape of the recess 21 can be formed as a part of a pyramidal surface. When a progression rate of the etching is gradually decreased while an etching range is narrowed, the shape of the recess 21 can be formed as a part of a paraboloid.

The recess 21 can also be formed by a micro-blasting method. Fine propellant is caused to be collided to the silicon semiconductor layer at high speed by a carrier gas such as compressed air, which allows the surface of the silicon semiconductor layer to be ground to form the recess 21. Fine powder made of alumina or silicon carbide may be used as the fine propellant, and a mask may be used in an arbitrary portion of the photodiode 10 in order that points except for the recess 21 are not ground by the fine propellant. When the processing is performed using a circular mask, the shape of the recess 21 can be formed as a part of the conical surface. When the processing is performed using a square mask, the shape of the recess 21 can be formed as a part of the pyramidal surface. When a processing rate is decreased while a range ground by the fine propellant is narrowed, the shape of the recess 21 can be formed as a part of the paraboloid.

The reflection plane 22 may be polished, in the case where the surface of the reflection plane 22 is not flat after the recess 21 is formed. Flip chip mounting of the light receiving device 101 allows a processable surface area of the photodiode 10 to be widened to enlarge a diameter of the recess 21.

The incident light 90 incident from the recess 21 of the photodiode 10 can be reflected to the depletion layer 11 by forming the reflection plane 22 in the recess 21. The reflection plane 22 reflects the incident light 90 toward the depletion layer 11. Accordingly, part of the light incident to the photodiode 10 can be focused onto the depletion layer 11 of the photodiode 10, which enables the provision of the light receiving device 101 which can efficiently receive the light.

Metal may adhere to the surface of the reflection plane 22. For example, metal such as gold, silver, and aluminum can be evaporated on the surface of the reflection plane 22 by an evaporation method. Metal such as gold, silver, and aluminum may also adhere to the surface of the reflection plane 22 by a sputtering method. Reflection efficiency of the reflection plane 22 can be enhanced by forming the metal on the surface of the reflection plane 22.

The shape of the recess 21 is preferably formed as a part of the paraboloid.

In the case where the shape of the recess 21 is formed as a part of the paraboloid, when the incident light 90 incident from the direction of a normal line of the surface having the depletion layer 11 of the photodiode 10 or from the direction near the normal line is incident to the side far away from the depletion layer 11 of the reflection plane 22, the incident light 90 is reflected at a shallow angle. When the incident light 90 incident from the direction of the normal line of the surface having the depletion layer 11 of the photodiode 10 or from the direction near the normal line is incident to the side near the depletion layer 11 of the reflection plane 22, the incident light 90 is reflected at a deep angle. That is, the incident light 90 incident from the direction of the normal line of the surface having the depletion layer 11 of the photodiode 10 or from the direction near the normal line is focused on the focus of the paraboloid irrespective of the position at which the incident light 90 is incident to the reflection plane 22.

When the depletion layer 11 is arranged near the paraboloid, the incident light 90 is reflected in the wide range of the depletion layer 11. Therefore, a margin is generated in accuracy when the die bonding is performed to the light receiving device 101, or a dynamic range of the light receiving device 101 can be released. Accordingly, part of the light incident to the photodiode 10 can be focused onto the depletion layer 11 of the photodiode 10, which enables the provision of the light receiving device 101 which can efficiently receive the light.

The depletion layer 11 is preferably arranged in a focus of the paraboloid.

As described above, in the case where the shape of the recess 21 is formed as a part of the paraboloid, when the incident light 90 incident from the direction of the normal line of the surface having the depletion layer 11 of the photodiode 10 or from the direction near the normal line is reflected from the reflection plane 22, the incident light 90 is focused onto the focus of the paraboloid. Therefore, the incident light 90 reflected from the reflection plane 22 is focused onto the depletion layer 11 by arranging the depletion layer 11 at the focus of the paraboloid. Accordingly, part of the light incident to the photodiode 10 can be focused onto the depletion layer 11 of the photodiode 10, which enables the provision of the light receiving device 101 which can efficiently receive the light.

The shape of the recess 21 can be formed as a part of the pyramidal surface.

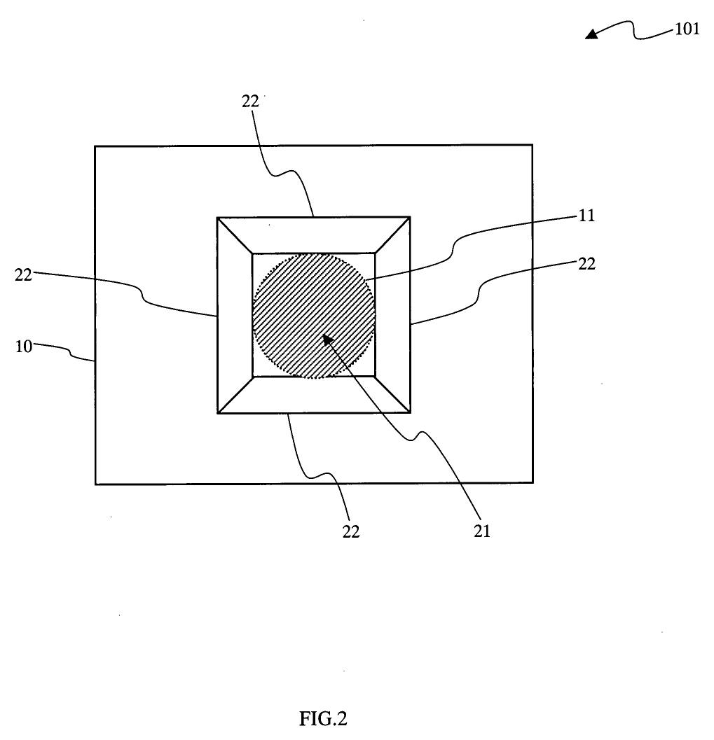

FIG. 2 is a top view showing the light receiving device 101 in which the shape of the recess 21 is formed as a part of a pyramidal surface. In FIG. 2, the same constituent is designated by the same numeral as FIG. 1. The depletion layer 11 is provided in the substrate and/or semiconductor layer in the surface opposite to the side of the surface in which the recess is formed.

In FIG. 2, because the reflection plane 22 is flat, the incident light incident from the direction of the normal line of the surface having the depletion layer 11 of the photodiode 10 or from the direction near the normal line is reflected at a constant reflection angle according to the incident angle, even if the incident light is incident to any position of the reflection plane 22. Therefore, the incident light reflected from the reflection plane 22 is not focused onto a particular portion of the depletion layer 11, but the incident light is reflected in the wide range of the depletion layer 11, so that an intensity distribution of the light incident to the depletion layer 11 can become even. Accordingly, the margin is generated in accuracy when the die bonding is performed to the light receiving device 101, or the dynamic range of the light receiving device 101 can be released.

The shape of the recess 21 can be formed as a part of the conical surface.

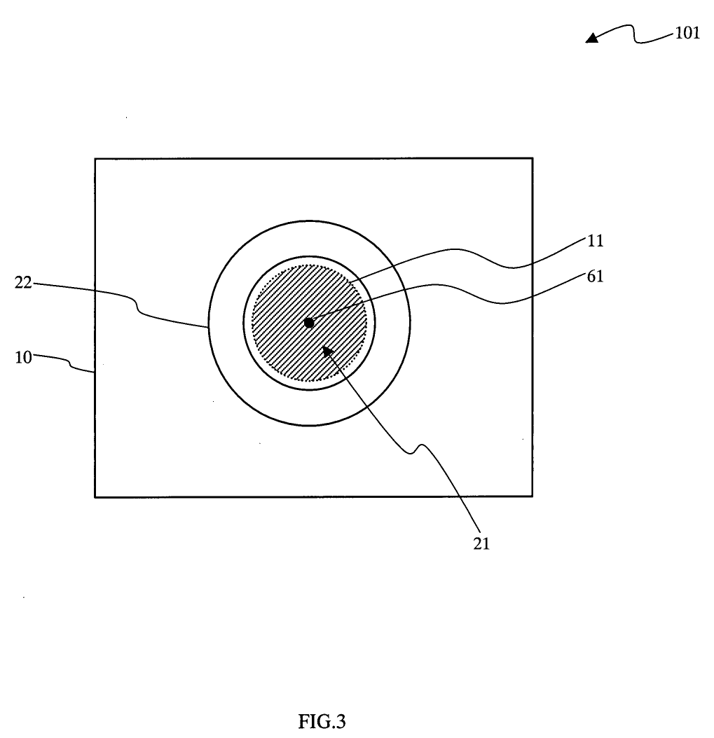

FIG. 3 is a top view showing the light receiving device 101 in which the shape of the recess 21 is formed as a part of a conical surface. In FIG. 3, the same constituent is designated by the same numeral as FIG. 1. The depletion layer 11 is provided in the substrate and/or semiconductor layer in the surface opposite to the side of the surface in which the recess of the photodiode 10 is formed. A center line 61 shall mean a line which passes through the center of the recess 21 formed as a part of the conical surface and is perpendicular to the surface having the depletion layer 11 of the photodiode 10.

In FIG. 3, because the reflection plane 22 is a part of a conical surface, the incident light 90 incident from the direction of the normal line of the surface having the depletion layer 11 of the photodiode 10 or from the direction near the normal line is reflected so as to pass through the center line 61 even if the incident light is incident to any position of the reflection plane 22. Therefore, the incident light reflected from the reflection plane 22 is focused on center line 61 of the depletion layer 11, which focuses the intensity distribution of the light incident to the depletion layer 11 on the center line 61. Accordingly, the light intensity distribution can be focused on the particular portion of the light receiving device 101.

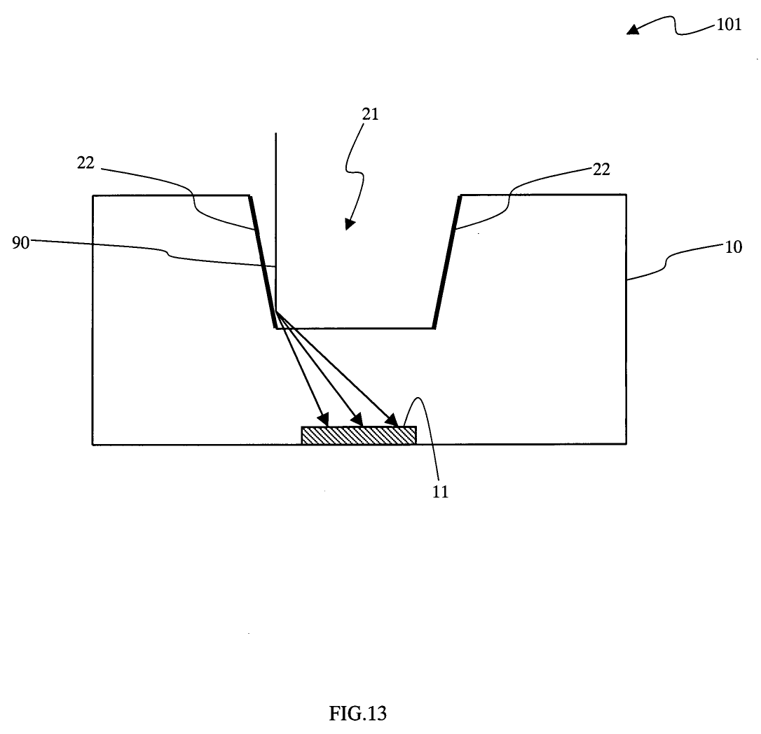

The surface of the reflection plane 22 may be roughened. FIG. 13 is a sectional view showing the light receiving device 101 in which the surface of the reflection plane 22 is roughened. In FIG. 13, the same constituent is designated by the same numeral as FIG. 1. The surface of the reflection plane 22 can be roughened by the micro-blasting method. When the surface of the reflection plane 22 is roughened, the incident light 90 incident from the direction of the normal line of the surface having the depletion layer 11 of the photodiode 10 or from the direction near the normal line is diffused and reflected in the wide range by the reflection plane 22 while not focused on the particular portion of the depletion layer 11, which allows the even intensity distribution of the light incident to the depletion layer 11. Accordingly, the margin is generated in accuracy when the die bonding is performed to the light receiving device 101, or the dynamic range of the light receiving device 101 can be released.

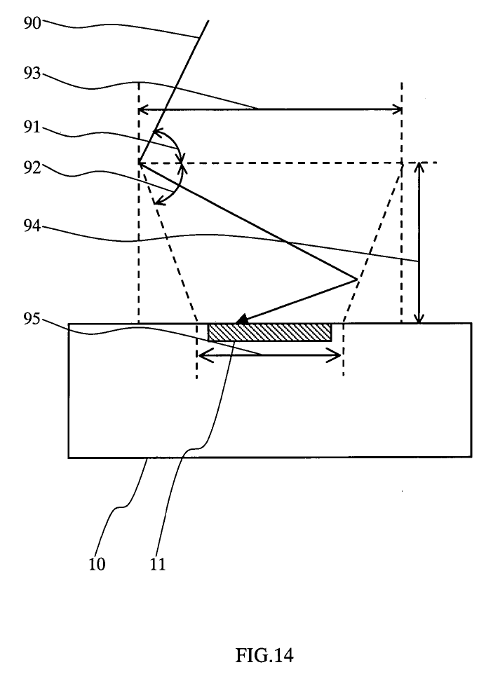

A relationship between a reflection-plane setting angle 92 and a reflection-plane height 94 will be described with reference to FIG. 14 which is of a sectional view of the photodiode 10. The invention is not limited to the examples of the reflection-plane setting angle 92 and reflection-plane height 94. An angle formed between the incident light 90 incident to the reflection plane 22 and the surface having the depletion layer 11 of the photodiode 10 is set at an incident-light incident angle 91, a setting angle of the reflection plane 22 with respect to the surface having the depletion layer 11 of the photodiode 10 is set at the reflection-plane setting angle 92, a diameter of a portion where an opening of the recess 21 becomes the maximum is set at a recess opening maximum diameter 93, a height of the normal line connecting the portion where the opening of the recess 21 becomes the maximum and the surface having the depletion layer 11 of the photodiode 10 is set at the reflection-plane height 94, and a diameter of a portion where the opening of the recess 21 becomes the minimum is set at a recess opening minimum diameter 95. In FIG. 14, the same constituent is designated by the same numeral as FIG. 1. When the diameter of the depletion layer 11 is increased, the photodiode 10 cannot be operated at high speed. When the setting angle 92 of the reflection plane 22 is decreased, although the reflection plane 22 can be broadened with respect to the incident light 90 incident from the direction of the normal line of the surface having the depletion layer 11 of the photodiode 10 or from the direction near the normal line, the incident light 90 cannot reach the depletion layer 11 even if the incident light 90 incident from the direction of the normal line of the surface having the depletion layer 11 of the photodiode 10 or from the direction near the normal line is reflected from the reflection plane 22.

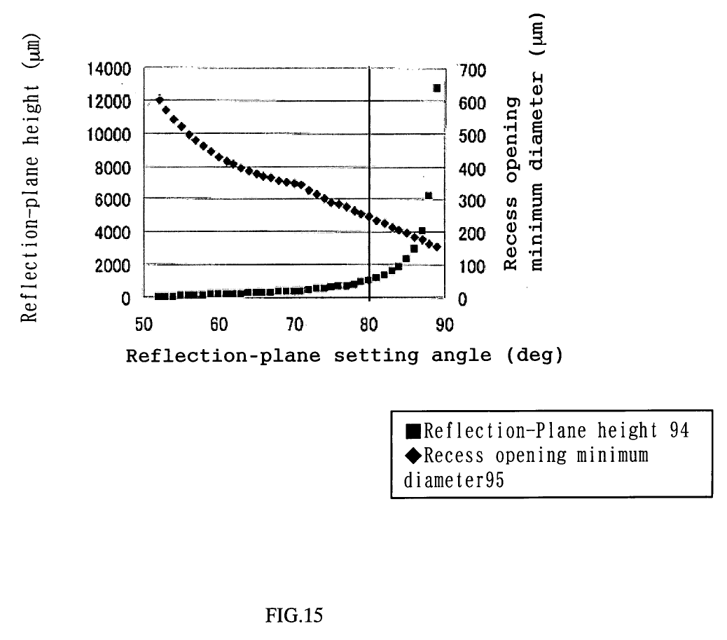

For example, the diameter of depletion layer 11 is set to 100 (μm), the incident-light incident angle 91 is set to 76 (deg), the recess opening maximum diameter 93 is set to 600 (μm), the recess opening minimum diameter 95 is set to 250 (μm), input intensity to the photodiode 10 is set to 0.4 (mW), and sensitivity of the a 2.5-Gbps receiving circuit is set to −20 (dBm). FIG. 15 shows the computation result of the relationship between the reflection-plane setting angle 92 and the reflection-plane height 94. In order to increase the reflection-plane setting angle 92 and to decrease the recess opening minimum diameter 95, it is necessary to increase the reflection-plane height 94. In order to decrease reflection-plane setting angle 92 and to cause the incident light 90 to reach the depletion layer 11, it is necessary to increase the recess opening minimum diameter 95. In the first embodiment, as can be seen from FIG. 15, when the reflection-plane setting angle 92 is set to 80 (deg), the reflection-plane height 94 corresponding to the reflection-plane setting angle 92 becomes 1000 (μm), for example.

### Second Embodiment

A second embodiment is a light receiving device including a photodiode which has a depletion layer on a side of one surface in two surfaces opposite to each other; a recess forming layer in which a recess is formed, the recess forming layer being deposited on the side of one surface of the photodiode or on the side of the other surface opposite to one surface; and the recess which is formed in the recess forming layer, wherein the recess has a reflection plane which reflects light incident from the side of the recess forming layer toward the depletion layer.

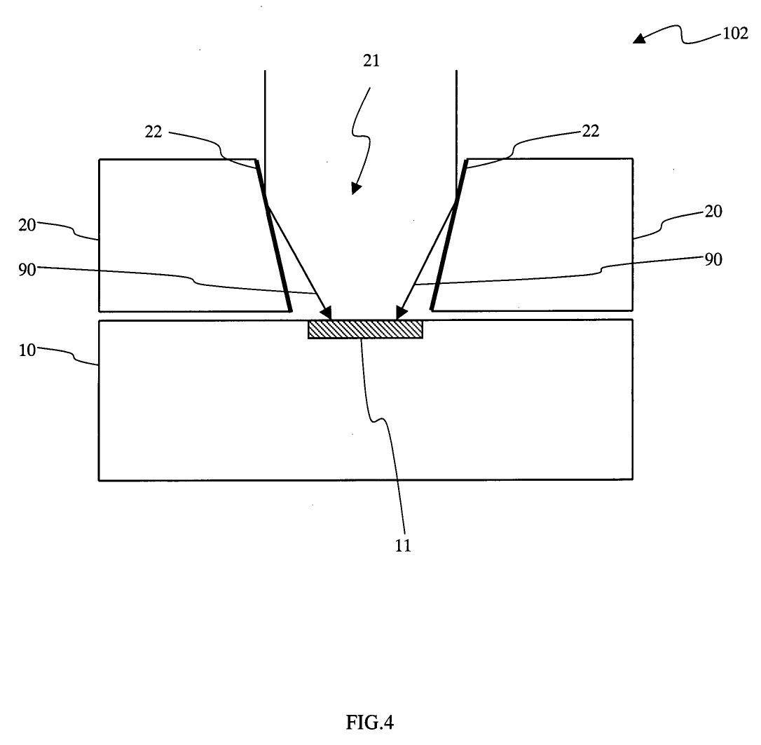

FIG. 4 is a sectional view showing a light receiving device 102 according to the second embodiment. Referring to FIG. 4, the light receiving device 102 includes the photodiode 10, the depletion layer 11, a recess forming layer 20, the recess 21, and the reflection plane 22. It is assumed that the light incident to the reflection plane 22 is the incident light 90. In FIG. 4, the same constituent is designated by the same numeral as FIG. 1.

In the photodiode 10 of FIG. 4, the recess forming layer 20 is deposited on the side of the surface having the depletion layer 11 or in the surface opposite to the side of the surface having the depletion layer 11. For example, the recess forming layer 20 can be made of an oxide, nitride, or metal thin film, or the recess forming layer 20 can be made of an epoxy or acrylic resin.

For example, a silicon-dioxide thin film can be obtained by heating the silicon substrate with high-temperature oxygen or water vapor to oxidize the surface of the silicon substrate. The silicon-dioxide thin film can also be obtained by a spin-on-glass (SOG) method. The silicon-dioxide thin film is deposited on the silicon substrate by performing spin coating of an SOG agent on the silicon substrate. In the SOG agent, a silicon compound is dissolved in an organic solvent. Alternatively, the epoxy or acrylic resin can be deposited by a resin spin coating method.

The recess 21 is formed on the recess forming layer 20. For example, in the silicon-dioxide thin film, the recess 21 can be formed by the reactive ion etching method or the micro-blasting method. In the silicon-dioxide thin film or the epoxy resin, the recess 21 can also be formed by die molding. The reflection plane 22 may be polished, in the case where the surface of the reflection plane 22 is not flat after the recess 21 is formed.

The incident light 90 incident from the recess forming layer 20 can be reflected to the depletion layer 11 of the photodiode 10 by forming the reflection plane 22 in the recess forming layer 20. The reflection plane 22 reflects the incident light 90 toward the depletion layer 11. Accordingly, part of the light incident to the photodiode 10 can be focused onto the depletion layer 11 of the photodiode 10, which enables the provision of the light receiving device 102 which can efficiently receive the light.

Metal may adhere to the surface of the reflection plane 22. For example, when the recess forming layer 20 is formed by the silicon-dioxide thin film, metal can adhere to the surface of the reflection plane 22 by the evaporation method or the sputtering method. In the case where the epoxy resin and the like is formed by a less heat-resistant material such as the printed substrate, as described above, metal may adhere to the surface of the reflection plane 22 by the plating. When metal is formed on the surface of the reflection plane 22 of FIG. 4, the light receiving device 102 provides with the same action and effect as the case in which metal is formed on the surface of the reflection plane 22 of FIG. 1.

The shape of the recess 21 is preferably formed as a part of the paraboloid.

When the shape of the recess 21 of FIG. 4 is formed as a part of the paraboloid, the light receiving device 102 provides with the same action and effect as the case in which the shape of the recess 21 of FIG. 1 is formed as a part of the paraboloid. Accordingly, part of the light incident to the photodiode 10 can be focused onto the depletion layer 11 of the photodiode 10, which enables the provision of the light receiving device 102 which can efficiently receive the light.

The depletion layer 11 is preferably arranged in the focus of the paraboloid.

When the depletion layer 11 of FIG. 4 is arranged in the focus of the paraboloid, the light receiving device 102 provides with the same action and effect as the case in which the depletion layer 11 of FIG. 1 is arranged in the focus of the paraboloid. Accordingly, part of the light incident to the photodiode 10 can be focused onto the depletion layer 11 of the photodiode 10, which enables the provision of the light receiving device 102 which can efficiently receive the light.

The shape of the recess 21 can be formed as a part of the pyramidal surface.

When the shape of the recess 21 of FIG. 4 is formed as a part of the pyramidal surface, the light receiving device 102 provides with the same action and effect as the case in which the shape of the recess 21 of FIG. 1 is formed as a part of the pyramidal surface.

The shape of the recess 21 can be formed as a part of the conical surface.

When the shape of the recess 21 of FIG. 4 is formed as a part of the conical surface, the light receiving device 102 provides with the same action and effect as the case in which the shape of the recess 21 of FIG. 1 is formed as a part of the conical surface.

The surface of the reflection plane 22 may be roughened. For example, the surface of the reflection plane 22 can be roughened by the micro-blasting method. When the surface of the reflection plane 22 is roughened, the light receiving device 102 provides with the same action and effect as the case in which the surface of the reflection plane 22 of FIG. 13 is roughened.

### Third Embodiment

A third embodiment is a light receiving device including a photodiode which has a depletion layer on a side of one surface in two surfaces opposite to each other; a plate-shape body which is arranged on the side of one surface of the photodiode or on the side of the other surface opposite to one surface; and a hole portion which penetrates the plate-shape body, wherein the hole portion has a reflection plane which reflects light incident from the side of the plate-shape body toward the depletion layer.

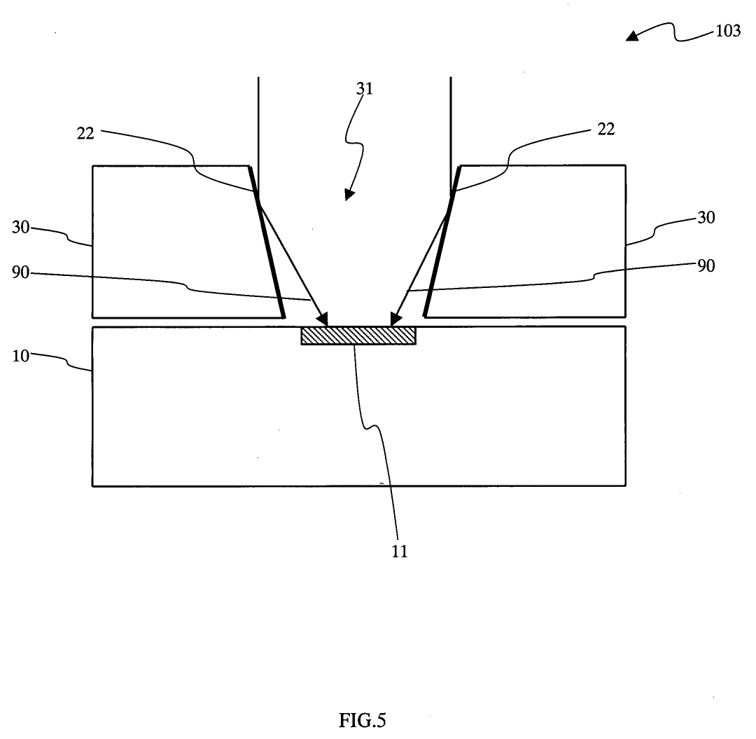

FIG. 5 is a sectional view showing a light receiving device 103 according to the third embodiment. Referring to FIG. 5, the light receiving device 103 includes the photodiode 10, the depletion layer 11, the reflection plane 22, a plate-shape body 30, and a hole portion (hereinafter referred to as through hole 31) which penetrates the plate-shape body 30. In FIG. 5, the same constituent is designated by the same numeral as FIG. 1.

In FIG. 5, the plate-shape body 30 includes the through hole 31. Examples of the plate-shape body 30 include a printed substrate, a substrate made of a material such as plastic, glass-epoxy, silicon dioxide (SiO₂), alumina, and aluminum nitride (AlN), a package made of a resin such as polypropylene (PP), or a ceramic package.

When the plate-shape body 30 is formed by the substrate made of silicon dioxide, alumina, or aluminum nitride or the ceramic package, the through hole 31 can be made by the reactive ion etching method. When the plate-shape body 30 is formed by the printed substrate, the substrate made of glass-epoxy and plastic, or the package made of the resin such as polypropylene, the through hole 31 can be made by the micro-blasting method. The reflection plane 22 may be polished, in the case where the surface of the reflection plane 22 is not flat after the through hole 31 is made.

In the photodiode 10, the plate-shape body 30 is arranged on the side of the surface having the depletion layer 11 of the photodiode 10 or in the surface opposite to the side of the surface having the depletion layer 11. In the case where the plate-shape body 30 is formed by the printed substrate or the substrate made of the material such as plastic, glass-epoxy, silicon dioxide, alumina, and aluminum nitride, the plate-shape body 30 is arranged on the side of the surface having the depletion layer 11 of the photodiode 10.

In the case where the plate-shape body 30 is formed by the package made of the resin such as polypropylene or the ceramic package, the plate-shape body 30 is arranged on the side of the surface having the depletion layer 11 of the photodiode 10 or in the surface opposite to the side of the surface having the depletion layer 11. Sometimes the photodiode 10 in which the plate-shape body 30 is arranged is arranged on the substrate. Because there are some methods of arranging the photodiode 10 on the substrate, each arranging method will be described with reference to the drawing.

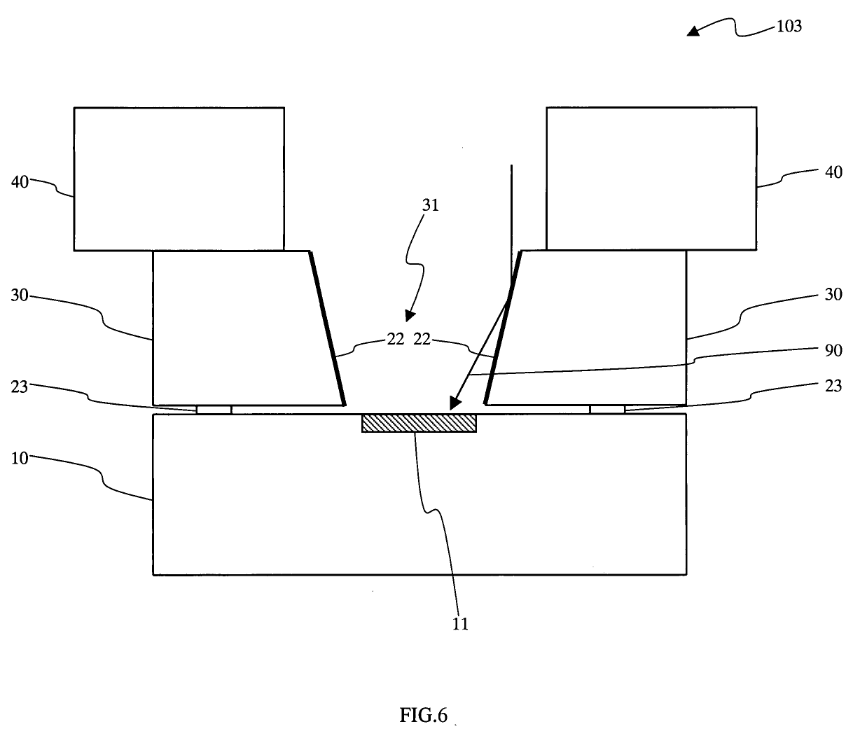

FIG. 6 shows one of the methods of arranging the photodiode 10 on the substrate. Referring to FIG. 6 the light receiving device 103 includes the photodiode 10, the depletion layer 11, the reflection plane 22, an electrode 23, the plate-shape body 30, the through hole 31, and a substrate 40. The plate-shape body 30 is formed by the resin package made of the material such as polypropylene, and the substrate 40 is a printed substrate. In FIG. 6, the same constituent is designated by the same numeral as FIG. 5.

The photodiode 10 includes at least one electrode 23 which is located in the surface having the depletion layer 11 and at a point except for the depletion layer 11. The through hole 31 is previously made in the plate-shape body 30, and the plate-shape body 30 is located while sandwiching the electrode 23 between the plate-shape body 30 and the surface having the depletion layer 11 of the photodiode 10.

The plate-shape body 30 may be located in the surface opposite to the side of the surface having the depletion layer 11 of the photodiode 10 (not shown in FIG. 6). Because the electrode 23 is located in the surface having the depletion layer 11 of the photodiode 10, the plate-shape body 30 may be located while sandwiching a supporting column between the plate-shape body 30 and the surface opposite to the side of the surface having the depletion layer 11 of the photodiode 10, or the plate-shape body 30 may be coupled to the surface opposite to the side of the surface having the depletion layer 11 of the photodiode 10 without sandwiching the supporting column.

Both in the case where the plate-shape body 30 is located on the side of the surface having the depletion layer 11 of the photodiode 10 and in the case where the plate-shape body 30 is located on the side of the opposite surface to the surface having the depletion layer 11 of the photodiode 10, the substrate 40 is arranged so as to be in contact with the surface on the side opposite to the side of the plate-shape body 30 on which the photodiode 10 is located.

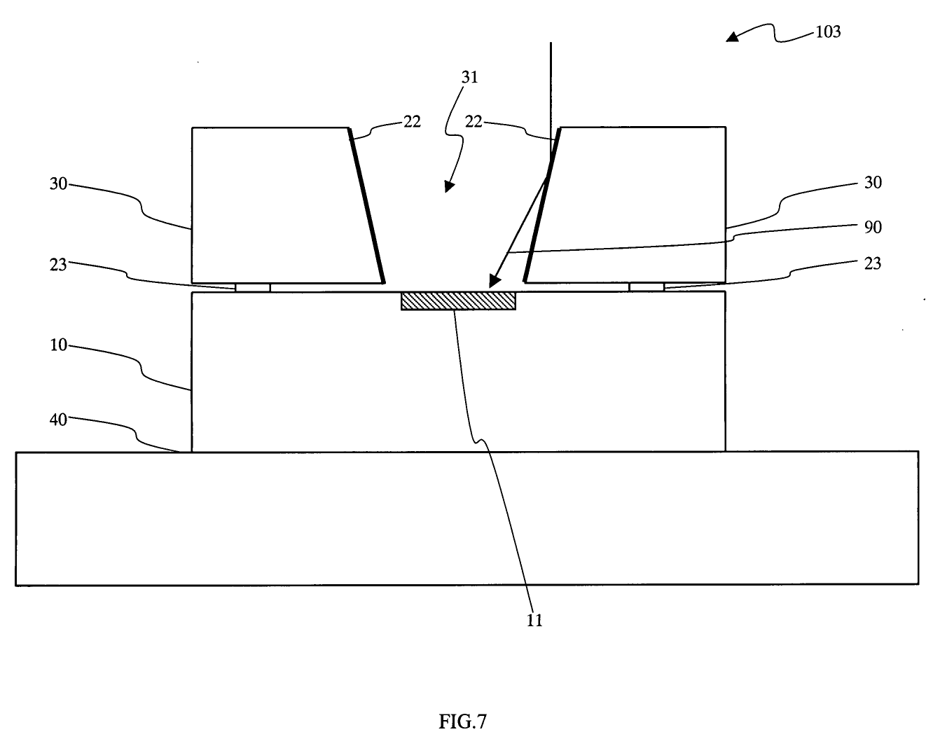

FIG. 7 shows another method of arranging the photodiode 10 in the substrate. Referring to FIG. 7, the light receiving device 103 includes the photodiode 10, the depletion layer 11, the reflection plane 22, the electrode 23, the plate-shape body 30, the through hole 31, and the substrate 40. The plate-shape body 30 is formed by the resin package made of the material such as polypropylene or the ceramic package, and the substrate 40 is the printed substrate. In FIG. 7, the same constituent is designated by the same numeral as FIG. 5.

The photodiode 10 of FIG. 7 includes at least one electrode 23 which is located in the surface having the depletion layer 11 and at a point except for the depletion layer 11. The through hole 31 is previously formed in the plate-shape body 30, and the plate-shape body 30 is located while sandwiching the electrode 23 between the plate-shape body 30 and the surface having the depletion layer 11 of the photodiode 10.

The plate-shape body 30 may be located in the surface opposite to the side of the surface having the depletion layer 11 of the photodiode 10 (not shown in FIG. 7). Because the electrode 23 is located in the surface having the depletion layer 11 of the photodiode 10, the plate-shape body 30 may be located while sandwiching the supporting column between the plate-shape body 30 and the surface opposite to the side of the surface having the depletion layer 11 of the photodiode 10, or the plate-shape body 30 may be coupled to the surface opposite to the side of the surface having the depletion layer 11 of the photodiode 10.

Both in the case where the plate-shape body 30 is located on the side of the surface having the depletion layer 11 of the photodiode 10 and in the case where the plate-shape body 30 is located on the side of the opposite surface to the surface having the depletion layer 11 of the photodiode 10, the substrate 40 is arranged so as to be in contact with the surface on the side opposite from the side of the plate-shape body 30 on which the photodiode 10 is located.

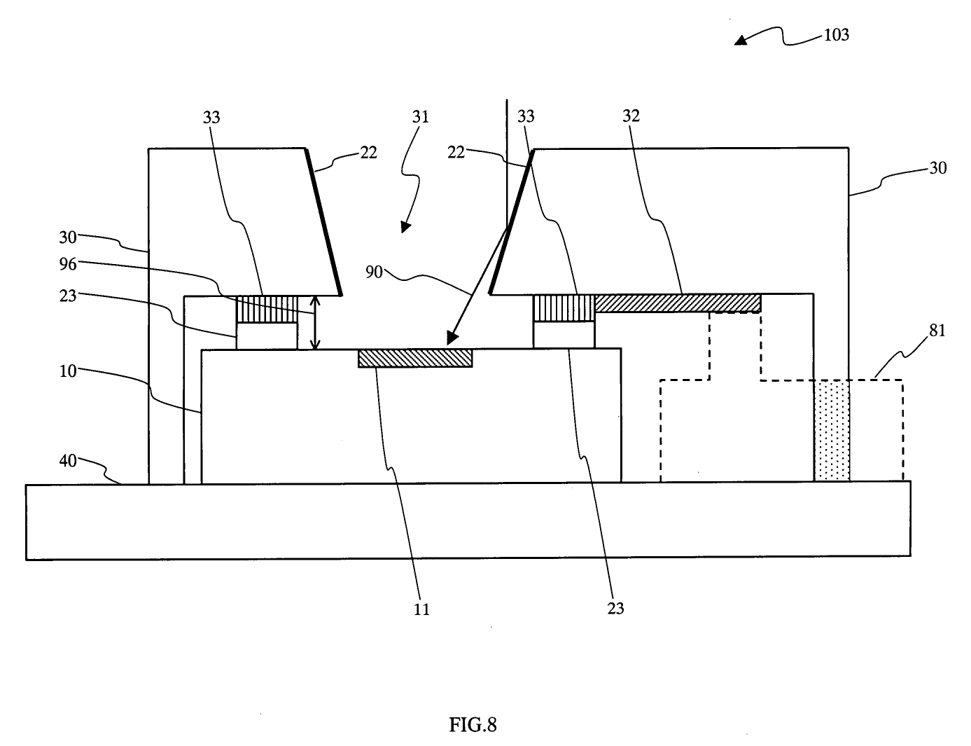

FIG. 8 shows another method of arranging the photodiode 10 in the substrate. For example, the photodiode 10 of FIG. 8 is connected to a trans-impedance amplifier 81. Referring to FIG. 8, the light receiving device 103 includes the photodiode 10, the depletion layer 11, the reflection plane 22, the electrode 23, the plate-shape body 30, the through hole 31, an interconnection 32, a bump 33, and the substrate 40. The plate-shape body 30 is formed by the resin package made of the material such as polypropylene or the ceramic package, and the substrate 40 is the printed substrate. In FIG. 8, the same constituent is designated by the same numeral as FIG. 5. The trans-impedance amplifier 81 has no relationship to the configuration of the light receiving device 103.

The photodiode 10 of FIG. 8 includes the electrode 23 which is located in the surface having the depletion layer 11 and at a point except for the depletion layer 11. The through hole 31, the interconnection 32, and the bump 33 are provided in the plate-shape body 30. The interconnection 32 and the bump 33 are provided in the surface on the side of the photodiode 10. The photodiode 10 and the plate-shape body 30 are arranged such that the electrode 23 and the bump 33 come into contact with each other. The interconnection 32 of the plate-shape body 30 can be connected to the transimpedance amplifier 81, so that the light receiving device 103 can be connected to the trans-impedance amplifier 81.

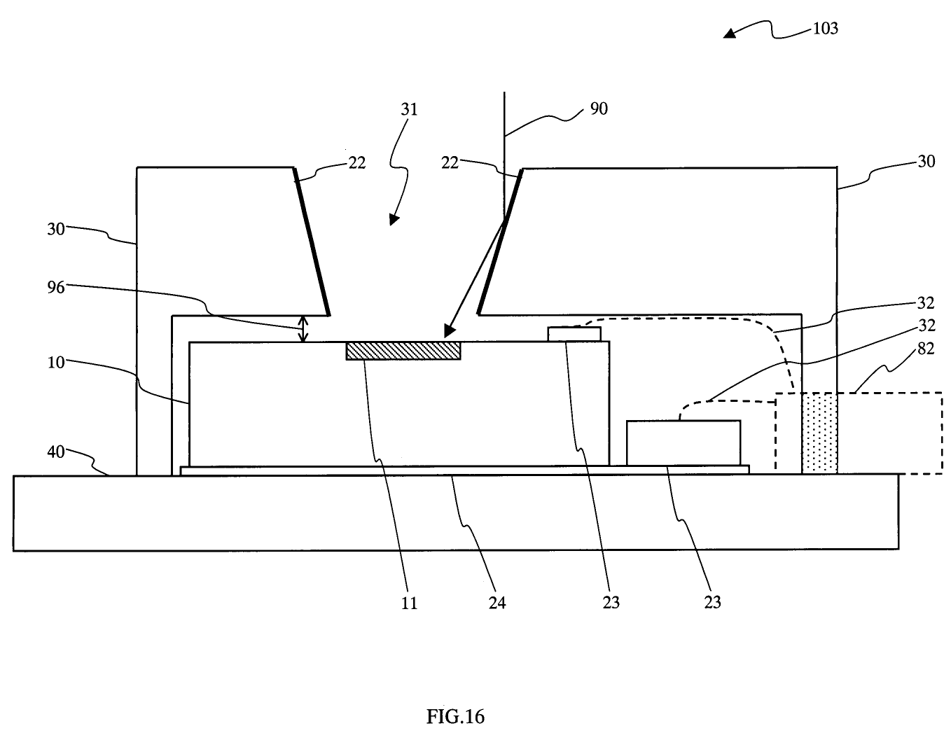

For example, the photodiode 10 of FIG. 16 is connected to an external IC 82 through the interconnection 32. The light receiving device 103 of FIG. 16 includes one electrode 23 which is located in the surface having the depletion layer 11 of the photodiode 10 and at a point except for the depletion layer 11. The light receiving device 103 also includes a plated-interconnection 24 between the photodiode 10 and the substrate 40. The plated-interconnection 24 also includes the other electrode 23 which is located in the surface on the side of the plate-shape body 30 of the plated-interconnection 24 and at a point except for the photodiode 10. The other electrode 23 is coupled by ball bonding. One electrode 23 is coupled by wedge bonding, which eliminates a ball necessary to the ball bonding. Therefore, a distance 96 can further be decreased, so that light receiving efficiency of the light receiving device 103 can be improved. In FIG. 16, the interconnection 32 and the external IC 82 have no relationship to the light receiving device 103.

In FIGS. 5, 6, 7, 8, and 16, the reflection plane 22 which reflects the incident light 90 toward the depletion layer 11 is formed in the plate-shape body 30, which allows the incident light 90 incident from the side of plate-shape body 30 to be reflected to the depletion layer 11 of the photodiode 10. Accordingly, part of the light incident to the photodiode 10 can be focused onto the depletion layer 11 of the photodiode 10, which enables the provision of the light receiving device 103 which can efficiently receive the light.

Metal may adhere to the surface of the reflection plane 22. For example, when the plate-shape body 30 is formed by the silicon-dioxide, alumina, or aluminum nitride substrate or the ceramic package, metal can adhere to the surface of the reflection plane 22 by the evaporation method or the sputtering method. In the case where the plate-shape body 30 is formed by a less heat-resistant material such as the printed substrate, the glass-epoxy or plastic substrate, and the resin package made of polypropylene and the like, as described above, metal may adhere to the surface of the reflection plane 22 by the plating. When metal is formed on the reflection plane 22 of FIGS. 5, 6, 7, 8, and 16, the light receiving device 103 provides with the same action and effect as the case in which metal is formed on the surface of the reflection plane 22 of FIG. 1.

The surface of the reflection plane 22 may be roughened. For example, the surface of the reflection plane 22 can be roughened by the micro-blasting method. When the surface of the reflection plane 22 of FIGS. 5, 6, 7, 8, and 16 is roughened, the light receiving device 103 provides with the same action and effect as the case in which the surface of the reflection plane 22 of FIG. 1 is roughened.

The shape of the through hole 31 is preferably formed as a part of the paraboloid.

When the shape of the through hole 31 of FIGS. 5, 6, 7, 8, and 16 is formed as apart of the paraboloid, the light receiving device 103 provides with the same action and effect as the case in which the shape of the recess 21 of FIG. 1 is formed as a part of the paraboloid. Accordingly, part of the light incident to the photodiode 10 can be focused onto the depletion layer 11 of the photodiode 10, which enables the provision of the light receiving device 103 which can efficiently receive the light.

The depletion layer 11 is preferably arranged in the focus of the paraboloid.

When the depletion layer 11 of FIGS. 5, 6, 7, 8, and 16 is arranged in the focus of the paraboloid, the light receiving device 103 provides with the same action and effect as the case in which the depletion layer 11 of FIG. 1 is arranged in the focus of the paraboloid. Accordingly, part of the light incident to the photodiode 10 can be focused onto the depletion layer 11 of the photodiode 10, which enables the provision of the light receiving device 103 which can efficiently receive the light.

The shape of the through hole 31 can be formed as a part of the pyramidal surface.

When the shape of the through hole 31 of FIGS. 5, 6, 7, 8, and 16 is formed as a part of the pyramidal surface, the light receiving device 103 provides with the same action and effect as the case in which the shape of the recess 21 of FIG. 1 is formed as a part of the pyramidal surface.

The shape of the through hole 31 can be formed as a part of the conical surface.

When the shape of the through hole 31 of FIGS. 5, 6, 7, 8, and 16 is formed as a part of the conical surface, the light receiving device 103 provides with the same action and effect as the case in which the shape of the recess 21 of FIG. 1 is formed as a part of the conical surface.

### Fourth Embodiment

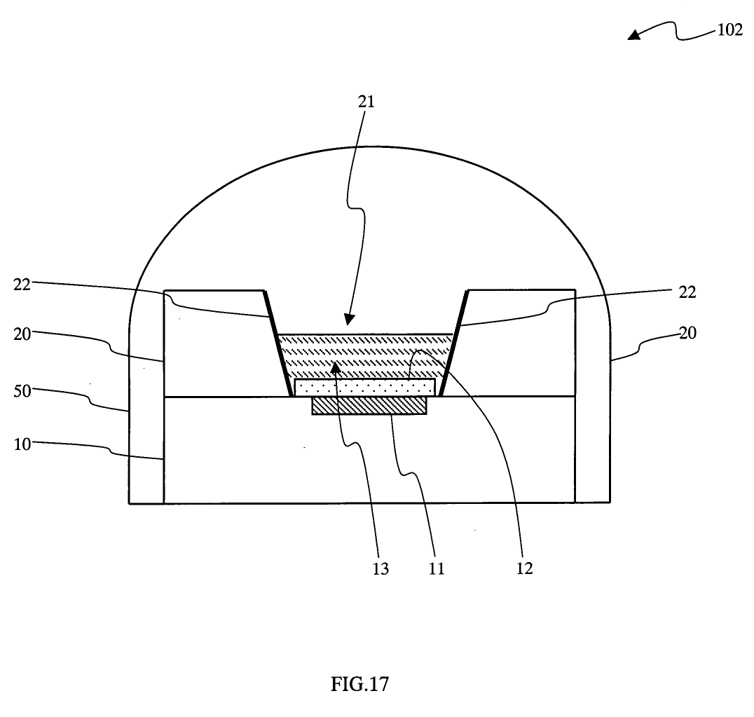

The photodiode 10 of the light receiving device 101, the light receiving device 102, and the light receiving device 103 may be accommodated in a housing 50 made of a resin such as epoxy and acryl. FIG. 17 is a sectional view showing the light receiving device 102 when the light receiving device 102 is accommodated in the housing. In FIG. 17, the same constituent is designated by the same numeral as FIG. 4.

When the photodiode 10 is accommodated by the housing 50, AR coating may be performed such that the surface of the depletion layer 11 is covered with an AR coating 12. In the case where a difference in refractive index is small between the resin of the housing 50 and an AR coating agent, when the photodiode 10 is accommodated by the housing 50 such that the AR coating 12 and the housing 50 are in contact with each other, transmission characteristics of the light receiving device 102 are largely degraded. For example, the refractive index of silicon dioxide (SiO₂) frequently used as the AR coating agent is 1.47, the refractive index of the epoxy resin is 1.5, and the difference in refractive index is small. Therefore, an air layer 13 is provided between the housing 50 and the AR coating 12, which allows the degradation of the transmission characteristics to be prevented in the light receiving device 102.

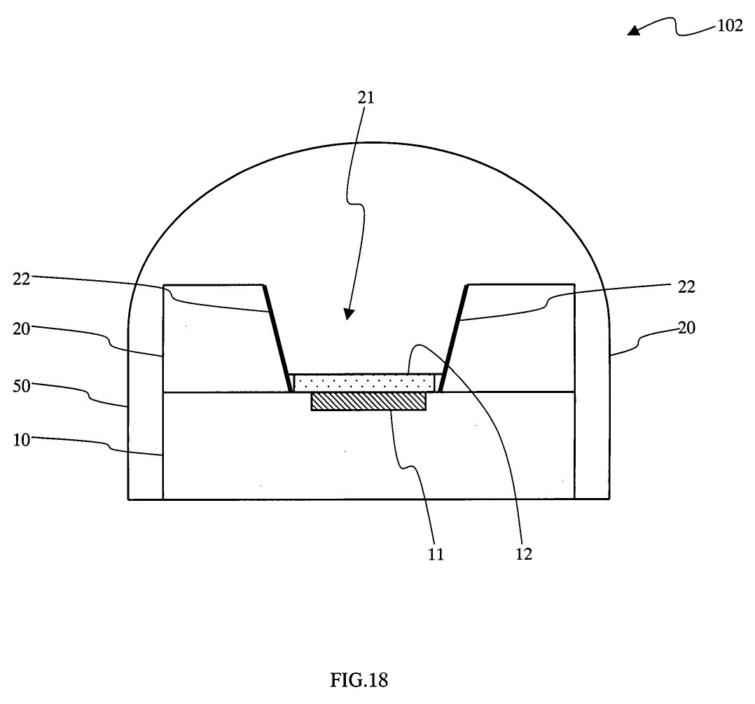

The difference in refractive index is increased between the resin of the housing 50 and the AR coating agent, which also allows the degradation of the transmission characteristics to be prevented in the light receiving device 102. For example, zinc oxide (ZnO) may be used as the AR coating agent. Zinc oxide having the refractive index of 2 is largely different from the epoxy resin having the refractive index of 1.5. Therefore, as shown in FIG. 18, even if the air layer 13 is not provided between the housing 50 and the AR coating 12 but the photodiode 10 is accommodated by the housing 50 such that the AR coating 12 and the housing 50 come into contact with each other, the degradation of the transmission characteristics can be prevented in the light receiving device 102. In FIG. 18, the same constituent is designated by the same numeral as FIG. 17.

### Fifth Embodiment

A fifth embodiment is a light receiving device including a photodiode which has a depletion layer on a side of one surface in two surfaces opposite to each other; a housing which accommodates the photodiode, at least one surface of the housing being opened; and a diffuser with which an inside of the housing is filled such that the photodiode is covered with the diffuser, the diffuser diffusing light.

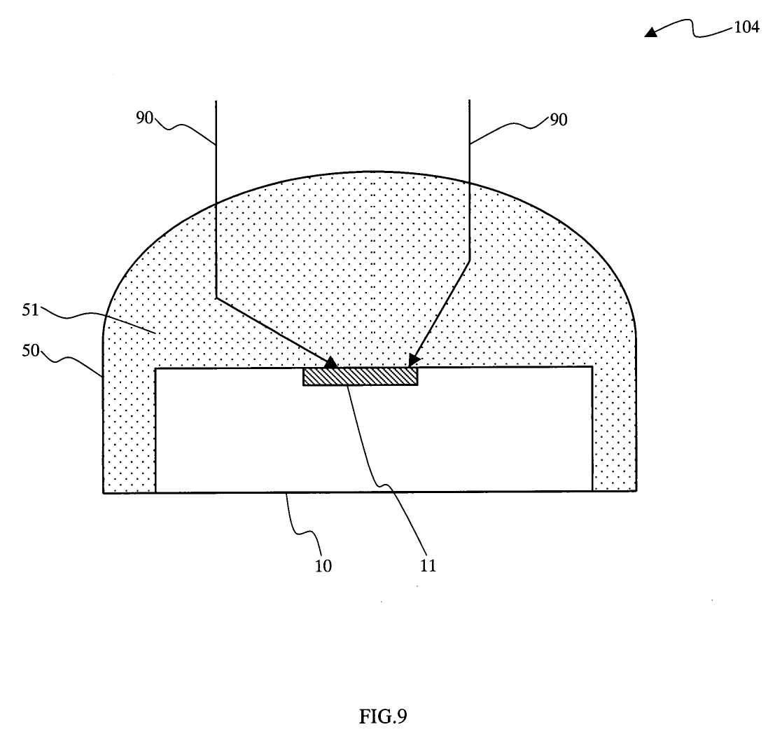

FIG. 9 is a sectional view showing a light receiving device 104 according to the fifth embodiment. Referring to FIG. 9, the light receiving device 104 includes the photodiode 10, the depletion layer 11, the housing 50, and a diffuser 51. It is assumed that the light incident to the housing 50 is the incident light 90.

The photodiode 10 of FIG. 9 which is comprised of a substrate and a semiconductor layer converts the light absorbed by the depletion layer 11 into the electric signal. Examples of the substrate of the photodiode 10 include the sapphire substrate and the semiconductor substrate made of group-IV single-element semiconductor such as silicon (Si) and germanium (Ge), group-III-V compound semiconductor such as indium phosphide (InP), galliumarsenide (GaAs), indium galliumar senide (InGaAs), gallium indium nitrogen arsenide (GaInNAs), aluminum gallium indium nitride (AlGaInN), aluminum indium gallium phosphide (AlInGaP), indium gallium arsenic phosphide (InGaAsP), and indium gallium aluminum arsenide (InGaAlAs), or group-II-VI compound semiconductor such as zinc oxide (ZnO), zinc selenide (ZnSe), and cadmium telluride (CdTe). Examples of the semiconductor layer of the photodiode 10 include the p-type semiconductor layer and the n-type semiconductor layer. The p-type semiconductor layer and the n-type semiconductor layer are deposited on the semiconductor substrate by adding the impurity to group-IV single-element semiconductor such as silicon and germanium, group-III-V compound semiconductor such as indium phosphide, gallium arsenide, indium gallium arsenide, gallium indium nitrogen arsenide, aluminum gallium indium nitride, aluminum indium gallium phosphide, indium gallium arsenic phosphide, and indium gallium aluminum arsenide, or group-II-VI compound semiconductor such as zinc oxide, zinc selenide, and cadmium telluride. Examples of the type of the photodiode 10 include the pn-photodiode, the pin-photodiode, and the avalanche photodiode.

The housing 50 is a container in which the photodiode 10 is accommodated. Examples of the housing 50 include a container made of a resin such as epoxy and acryl and a metal container. An example of the diffuser 51 includes one in which a light diffusing material such as calcium sulfate, calcium carbonate, barium sulfate, aluminum oxide, aluminum silicate, and titanium oxide is mixed into the epoxy or acrylic resin.

The inside of the housing 50 is filled with the diffuser 51, which diffuses the light, such that the photodiode 10 is covered. For example, the inside of the housing 50 may be filled with the diffuser 51 after the inside of the housing 50 is hollowed out. The housing 50 may be formed using the diffuser 51 as a material. When the photodiode 10 is accommodated by the housing 50, the incident light 90 incident to the housing 50 is diffused by the diffuser 51 with which the housing 50 is filled.

In the case of the housing 50 which is not filled with the diffuser 51, even for the incident light 90 which is incident at the angle and position at which the incident light 90 does not reach the depletion layer 11, the housing 50 is filled with the diffuser 51 to diffuse the incident light 90, which allows the incident light 90 to be sometimes incident to the depletion layer 11. Accordingly, part of the light incident to the photodiode 10 is caused to reach the depletion layer 11 of the photodiode 10, which enables the provision of the light receiving device 104 which can efficiently receive the light.

The diffuser is preferably made of the plural mixed transparent materials having the different refractive indexes.

Examples of the transparent material include the epoxy resin and the acrylic resin. In the case of the housing 50 which is not filled with the diffuser 51, even for the incident light 90 which is incident at the angle and position at which the incident light 90 does not reach the depletion layer 11, the housing 50 is filled with the diffuser 51 in which the plural transparent materials having the different refractive indexes are mixed to refract the incident light 90, which allows the incident light 90 to be sometimes incident to the depletion layer 11. In the housing 50 in which the diffusers 51 including the transparent materials are mixed, part of the incident light 90 incident to the housing 50 is not absorbed, but refracted to reach the depletion layer 11. Accordingly, part of the light incident to the photodiode 10 is caused to reach the depletion layer 11 of the photodiode 10, which enables the provision of the light receiving device 104 which can efficiently receive the light.

The diffuser 51 is preferably arranged while removed the portion immediately above the depletion layer 11.

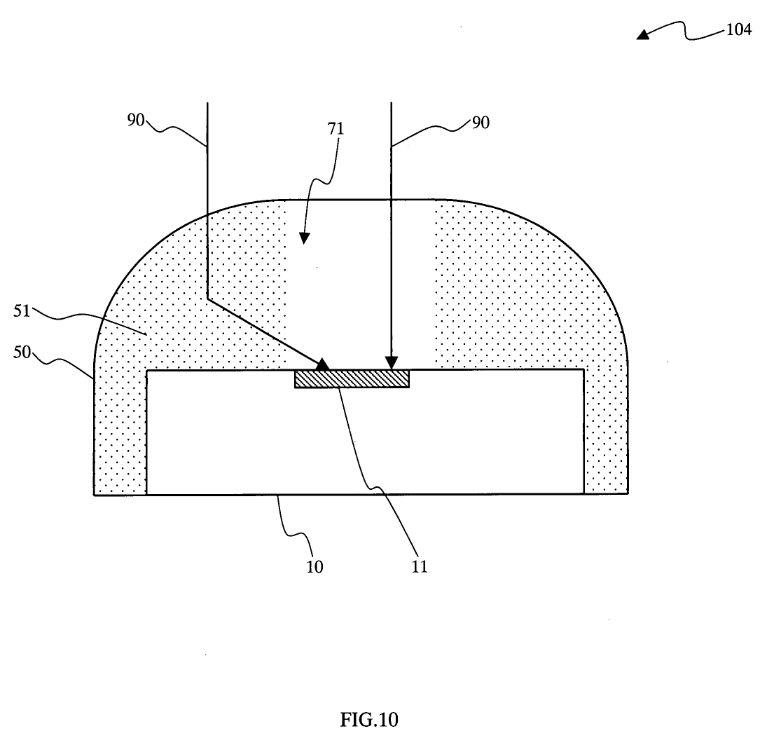

FIG. 10 is a sectional view showing the light receiving device 104 in which the diffuser 51 is preferably arranged while removed the portion immediately above the depletion layer 11. It is assumed that the portion immediately above the depletion layer 11 is an optical path 71. In FIG. 10, the same constituent is designated by the same numeral as FIG. 9.

When the inside of the housing 50 of FIG. 10 is filled with the diffuser 51 such that the photodiode 10 is covered, because the light incident to the optical path 71 is also diffuse or refracted, sometimes the incident light 90 does not reach the depletion layer 11. When the diffuser 51 is arranged while removed the optical path 71, the light incident to the optical path 71 is not diffused or refracted. Sometimes the light incident to the housing 50 except for the optical path 71 is incident to the depletion layer 11 because the light is diffused or refracted by the diffuser 51. The optical path 71 may be hollowed out, or the optical path 71 may be filled with the transparent material such as the epoxy resin. Accordingly, part of the light incident to the photodiode 10 is caused to reach the depletion layer 11 of the photodiode 10, which enables the provision of the light receiving device 104 which can efficiently receive the light.

### Sixth Embodiment

A sixth embodiment is a light receiving device including a photodiode which has a depletion layer on a side of one surface in two surfaces opposite to each other; a housing which accommodates the photodiode, at least one surface of the housing being opened; and a diffuser which is provided in the housing, the diffuser diffusing light incident to the depletion layer of the photodiode.

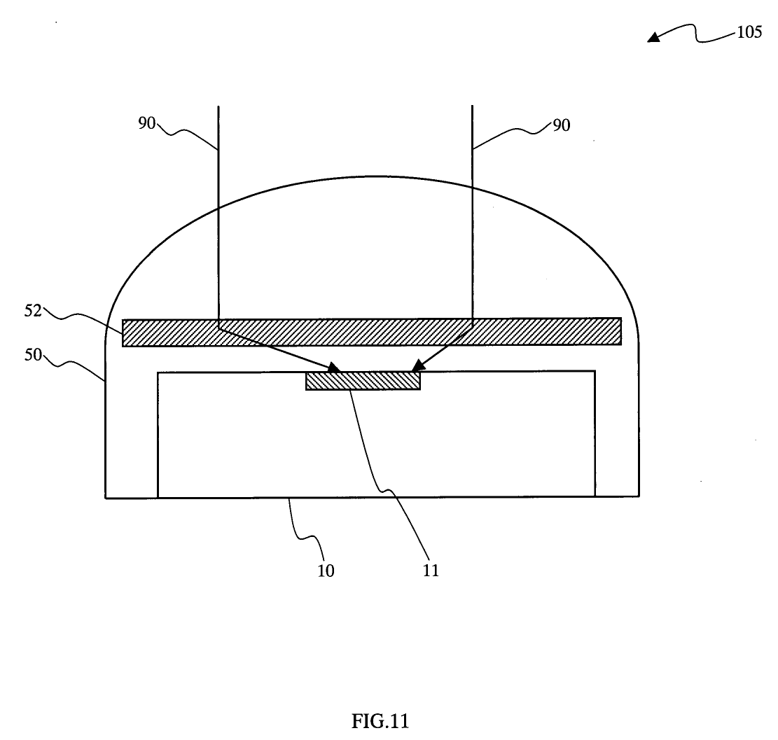

FIG. 11 is a sectional view showing a light receiving device 105 according to the sixth embodiment. Referring to FIG. 11, the light receiving device 105 includes the photodiode 10, the depletion layer 11, the housing 50, and a plate-shape diffuser (hereinafter referred to as diffuser plate 52). In FIG. 11, the same constituent is designated by the same numeral as FIG. 9.

The housing 50 of FIG. 11 includes the diffuser plate 52 therein. An example of the diffuser plate 52 includes a diffuser in which the light diffusing material such as calcium sulfate, calcium carbonate, barium sulfate, aluminum oxide, aluminum silicate, and titanium oxide is mixed into the epoxy or acrylic resin and formed in the plate shape.

For example, the diffuser plate 52 may horizontally be coupled to the housing 50 such that the diffuser plate 52 is sandwiched by the both sides of the housing 50. Alternatively, a groove into which the diffuser plate 52 can be inserted may be provided in the housing 50 to fit the diffuser plate 52 in the groove.

When the photodiode 10 is accommodated by the housing 50, the incident light 90 incident to the housing 50 is diffused by the diffuser plate 52 included in the housing 50. Therefore, in the case of the housing 50 not including the diffuser plate 52, even for the incident light 90 which is incident at the angle and position at which the incident light 90 does not reach the depletion layer 11, sometimes the incident light 90 is diffused to be incident to the depletion layer 11 by providing with the diffuser plate 52 in the housing 50. Accordingly, part of the light incident to the photodiode 10 is caused to reach the depletion layer 11 of the photodiode 10, which enables the provision of the light receiving device 105 which can efficiently receive the light.

The diffuser plate 52 is preferably made of the plural mixed transparent materials having the different refractive indexes.

The diffuser plate 52 may be formed by mixing the plural transparent materials having the different refractive indexes. Examples of the transparent material include the epoxy resin and the acrylic resin. When the diffuser plate 52 of FIG. 11 is made of the transparent materials having the different refractive indexes, the light receiving device 105 provides with the same action and effect as the case in which the diffuser 51 of FIG. 10 is made of the transparent materials having the different refractive indexes. Accordingly, part of the light incident to the photodiode 10 is caused to reach the depletion layer 11 of the photodiode 10, which enables the provision of the light receiving device 105 which can efficiently receive the light.

The diffuser plate 52 is arranged while removed a portion immediately above the depletion layer 11.

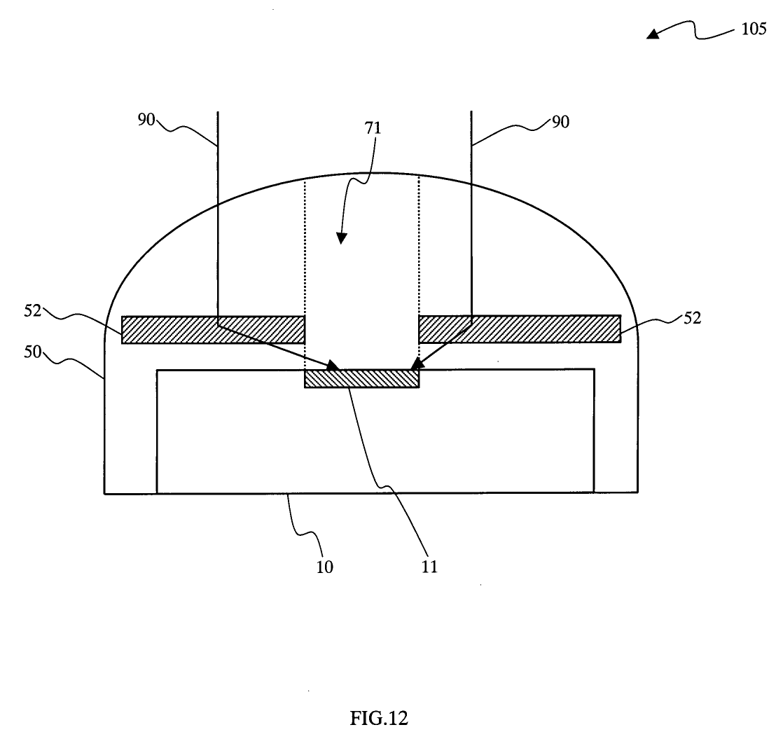

FIG. 12 is a sectional view showing the light receiving device 105 in which the diffuser plate 52 is arranged while removed a portion immediately above the depletion layer 11. In FIG. 12, the same constituent is designated by the same numeral as FIG. 10.

When the diffuser plate 52 of FIG. 12 is arranged while removed the optical path 71, the light receiving device 105 provides with the same action and effect as the case in which the diffuser 51 of FIG. 10 is arranged while removed the optical path 71. The optical path 71 may be hollowed out, or the optical path 71 may be filled with the transparent material such as the epoxy resin. Accordingly, part of the light incident to the photodiode 10 is caused to reach the depletion layer 11 of the photodiode 10, which enables the provision of the light receiving device 105 which can efficiently receive the light.

The light receiving device of the invention can be applied to the light receiving element for CCD or the optical fiber.

What is claimed is:

1. A light receiving device comprising:
a photodiode which has a depletion layer on a side of one surface in two surfaces opposite to each other; and
a recess which is provided in a substrate and/or a semiconductor layer on the side of the other surface opposite to one surface of the photodiode,
wherein the recess has a reflection plane which reflects light incident from the side of the other surface of the photodiode toward the depletion layer, and the light transmits the inside of the substrate and/or the semiconductor layer to the depletion layer.

2. A light receiving device comprising:
a photodiode which has a depletion layer on a side of one surface in two surfaces opposite to each other;
a recess forming layer in which a recess is formed, the recess forming layer being deposited on the side of one surface of the photodiode or on the side of the other surface opposite to one surface; and
the recess which is formed in the recess forming layer,
wherein the recess has a reflection plane which reflects light incident from the side of the recess forming layer toward the depletion layer.

3. The light receiving device according to claims 1 or 2,
wherein a shape of the recess is a part of a paraboloid.

4. A light receiving device comprising:
a photodiode which has a depletion layer on a side of one surface in two surfaces opposite to each other;
a plate-shape body which is arranged on the side of one surface of the photodiode or on the side of the other surface opposite to one surface; and
a hole portion which penetrates the plate-shape body,
wherein the hole portion has a reflection plane which reflects light incident from the side of the plate-shape body toward the depletion layer.

5. The light receiving device according to claim 4,
wherein the shape of the hole portion is a part of the paraboloid.

6. The light receiving device according to claim 3,
wherein the depletion layer is arranged in a focus of the paraboloid.

7. The light receiving device according to claim 5,
wherein the depletion layer is arranged in the focus of the paraboloid.

8. A light receiving device comprising:
a photodiode which has a depletion layer on a side of one surface in two surfaces opposite to each other;
a housing which accommodates the photodiode, at least one surface of the housing being opened; and
a diffuser with which an inside of the housing is filled so as to cover the photodiode, the diffuser diffusing light.

9. A light receiving device comprising:
a photodiode which has a depletion layer on a side of one surface in two surfaces opposite to each other;
a housing which accommodates the photodiode, at least one surface of the housing being opened; and
a diffuser which is provided in the housing, the diffuser diffusing light incident to the depletion layer of the photodiode.

10. The light receiving device according to claims 8 or 9,
wherein the diffuser is made of a plurality of mixed transparent materials having different refractive indexes.

11. The light receiving device according to claims 8 or 9,
wherein the diffuser is arranged while removed a portion immediately above the depletion layer.
